(19) United States
(12) Patent Application Publication
(10) Pub. No.: US 2025/0071894 A1
(43) Pub. Date: Feb. 27, 2025

(54) PRINTED WIRING BOARD SUBSTRATE, PRINTED WIRING BOARD, AND MULTILAYER PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Hiroshi UEDA, Osaka (JP); Ichiro KUWAYAMA, Osaka (JP); Suguru YAMAGISHI, Osaka (JP); Toshiki IWASAKI, Osaka (JP); Akihiro YANO, Shiga (JP); Takuma YAMAMOTO, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/848,555

(22) PCT Filed: Mar. 20, 2023
(86) PCT No.: PCT/JP2023/010854

§ 371 Date: Sep. 19, 2024

(30) Foreign Application Priority Data
Mar. 29, 2022 (JP) 2022-053269

(51) Int. Cl. H05K 1/03; H05K 1/02; H05K 1/09

(52) U.S. Cl. CPC H05K 1/036; H05K 1/0237; H05K 1/09; H05K 2201/015; H05K 2201/0154; H05K 2201/0355; H05K 2201/068

(57) ABSTRACT

The printed wiring board substrate includes an insulating layer, a first copper foil, and a second copper foil. The insulating layer has a first main surface and a second main surface opposite to the first main surface. The insulating layer includes a plurality of polyimide layers and a plurality of fluororesin layers. The total number of the plurality of polyimide layers and the plurality of fluororesin layers is 5 or more. Each of the plurality of polyimide layers and each of the plurality of fluororesin layers are alternately stacked along a thickness direction of the insulating layer. One of the plurality of fluororesin layers constitutes a first outermost layer which is an outermost layer on the side of the first main surface. Another one of the plurality of fluororesin layers constitutes a second outermost layer which is an outermost layer on the side of the second main surface.

### TECHNICAL FIELD

The present disclosure relates to a printed wiring board substrate, a printed wiring board, and a multilayer printed wiring board. The present application claims the benefit of priority to Japanese Patent Application No. 2022-053269 filed on Mar. 29, 2022. The entire contents described in the Japanese Patent Application are incorporated herein by reference.

### BACKGROUND ART

WO 2010/084867 (PTL 1) describes a multilayer fluororesin film. The multilayer fluororesin film described in PTL 1 is used, for example, in a printed wiring board. The multilayer fluororesin film described in PTL 1 includes three polyimide films and two fluororesin films. In the multilayer fluororesin film described in PTL 1,the polyimide films and the fluororesin films are alternately stacked so that the polyimide film constitutes an outermost layer. A copper foil is disposed on the outermost polyimide film.

### CITATION LIST

### Patent Literature

PTL 1: WO 2010/084867

### SUMMARY OF INVENTION

A printed wiring board substrate of the present disclosure includes an insulating

layer, a first copper foil, and a second copper foil. The insulating layer has a first main surface and a second main surface opposite to the first main surface. The insulating layer includes a plurality of polyimide layers and a plurality of fluororesin layers. The total number of the plurality of polyimide layers and the plurality of fluororesin layers is 5 or more. Each of the plurality of polyimide layers and each of the plurality of fluororesin layers are alternately stacked along a thickness direction of the insulating layer. One of the plurality of fluororesin layers constitutes a first outermost layer which is an outermost layer on the side of the first main surface. Another one of the plurality of fluororesin layers constitutes a second outermost layer which is an outermost layer on the side of the second main surface. The first outermost layer and the second outermost layer each have a thickness of 1.0 μm or more and 50 μm or less. A value obtained by dividing a total thickness of the plurality of polyimide layers by a thickness of the insulating layer is 0.95 or less. The first copper foil and the second copper foil are disposed on the first main surface and the second main surface, respectively.

### BRIEF DESCRIPTION OF DRAWINGS

FIG. 1 is a cross-sectional view of a printed wiring board substrate 100;

FIG. 2 is a cross-sectional view of a printed wiring board 200; and

FIG. 3 is a cross-sectional view of a multilayer printed wiring board 300.

### DETAILED DESCRIPTION

### [Problem to be Solved by the Present Disclosure]

However, in the multilayer fluororesin film described in PTL 1, it is difficult to achieve both good high-frequency property and good bending property. The present disclosure has been made in view of the above-mentioned problem

of the prior art. More specifically, an object of the present disclosure is to provide a printed wiring board substrate, a printed wiring board, and a multilayer printed wiring board capable of achieving both good high-frequency property and good bending property.

### [Advantageous Effect of the Present Disclosure]

According to the printed wiring board substrate of the present disclosure, it is possible to achieve both good high-frequency property and good bending property.

### [Description of Embodiments of the Present Disclosure]

First, embodiments of the present disclosure will be described.

(1) A printed wiring board substrate according to an embodiment includes an insulating layer, a first copper foil, and a second copper foil. The insulating layer has a first main surface and a second main surface opposite to the first main surface. The insulating layer includes a plurality of polyimide layers and a plurality of fluororesin layers. The total number of the plurality of polyimide layers and the plurality of fluororesin layers is 5 or more. Each of the plurality of polyimide layers and each of the plurality of fluororesin layers are alternately stacked along a thickness direction of the insulating layer. One of the plurality of fluororesin layers constitutes a first outermost layer which is an outermost layer on the side of the first main surface. Another one of the plurality of fluororesin layers constitutes a second outermost layer which is an outermost layer on the side of the second main surface. The first outermost layer and the second outermost layer each have a thickness of 1.0 μm or more and 50 μm or less. A value obtained by dividing a total thickness of the plurality of polyimide layers by a thickness of the insulating layer is 0.95 or less. The first copper foil and the second copper foil are disposed on the first main surface and the second main surface, respectively.

According to the printed wiring board substrate of (1), it is possible to achieve both good high-frequency property and good bending property.

(2) In the printed wiring board substrate of (1), the plurality of fluororesin layers may be made of at least one material selected from the group consisting of tetrafluoroethylene-hexafluoropropylene copolymer, tetrafluoroethylene-perfluoroalkyl vinyl ether copolymer, and polytetrafluoroethylene.

(3) In the printed wiring board of (1) or (2), the plurality of polyimide layers may be made of polyimide having a relative dielectric constant of 2 or more and 4 or less.

According to the printed wiring board substrate of (3), it is further possible to achieve good high-frequency property.

(4) In the printed wiring board substrate according to any one of (1) to (3), the first copper foil and the second copper foil may be made of electrolytic copper foil.

(5) In the printed wiring board substrate according to any one of (1) to (3), the first copper foil and the second copper foil may be made of rolled copper foil.

According to the printed wiring board substrate of (5), it is further possible to achieve good bending property.

(6) In the printed wiring board substrate according to any one of (1) to (5), the insulating layer may have a thermal expansion coefficient of 16.0 ppm/K or more and 100 ppm/K or less.

(7) In the printed wiring board substrate according to any one of (1) to (6), the insulating layer may have a thickness of 170 μm or less.

According to the printed wiring board substrate of (7), it is further possible to achieve good bending property.

(8) A printed wiring board according to an embodiment includes an insulating layer, a first wiring, and a second wiring. The insulating layer has a first main surface and a second main surface opposite to the first main surface. The insulating layer includes a plurality of polyimide layers and a plurality of fluororesin layers. The total number of the plurality of polyimide layers and the plurality of fluororesin layers is 5 or more. Each of the plurality of polyimide layers and each of the plurality of fluororesin layers are alternately stacked along a thickness direction of the insulating layer. One of the plurality of fluororesin layers constitutes a first outermost layer which is an outermost layer on the side of the first main surface. Another one of the plurality of fluororesin layers constitutes a second outermost layer which is an outermost layer on the side of the second main surface. The first outermost layer and the second outermost layer each have a thickness of 1.0 μm or more and 50 μm or less. A value obtained by dividing a total thickness of the plurality of polyimide layers by a thickness of the insulating layer is 0.95 or less. The first wiring and the second wiring are disposed on the first main surface and the second main surface, respectively.

According to the printed wiring board of (8), it is possible to achieve both good high-frequency property and good bending property.

(9) In the printed wiring board of (8), the transmission loss per 100 mm of the first wiring at 50 GHz and the transmission loss per 100 mm of the second wiring at 50 GHz may be 7 dB or less.

According to the printed wiring board of (9), it is further possible to achieve good high-frequency property.

(10) A multilayer printed wiring board according to an embodiment includes a plurality of printed wiring boards. Each of the plurality of printed wiring boards is the printed wiring board according to (8) or (9).

According to the multilayer printed wiring board of (10), it is possible to achieve both good high-frequency property and good bending property.

### [Details of Embodiments of the Present Disclosure]

Embodiments of the present disclosure will be described in detail with reference to the drawings. In the following drawings, the same or corresponding portions will be denoted by the same reference numerals, and the description thereof will not be repeated.

### (Printed Wiring Board Substrate According to an Embodiment)

A printed wiring board substrate according to an embodiment will be described. Hereinafter, the printed wiring board substrate according to the embodiment is defined as a printed wiring board substrate 100.

### <Configuration of Printed Wiring Board Substrate 100>

Hereinafter, the configuration of the printed wiring board substrate 100 will be described.

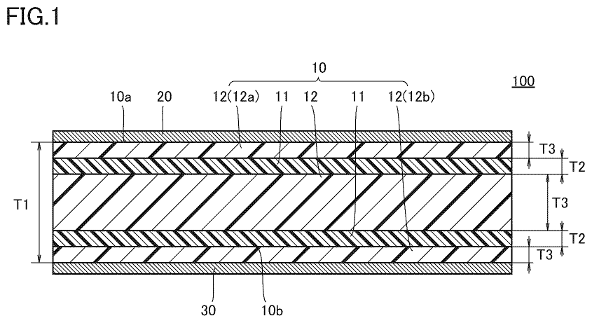

FIG. 1 is a cross-sectional view of the printed wiring board substrate 100. As illustrated in FIG. 1, the printed wiring board substrate 100 includes an insulating layer 10, a first copper foil 20, and a second copper foil 30.

The insulating layer 10 has a first main surface 10a and a second main surface 10b. The first main surface 10a and the second main surface 10b are end surfaces of the insulating layer 10 in the thickness direction. The thickness of the insulating layer 10 is defined as thickness T1. The thickness T1 is, for example, 170 μm or less.

The thermal expansion coefficient of the insulating layer 10 is preferably 16.0ppm/K or more and 100 ppm/K or less. The thermal expansion coefficient of the insulating layer 10 is measured by thermal mechanical analysis (TMA). The thermal expansion coefficient of the insulating layer 10 is measured in the in-layer direction of the insulating layer 10. The in-layer direction of the insulating layer 10 is orthogonal to the thickness direction of the insulating layer 10.

The insulating layer 10 includes a plurality of polyimide layers 11 and a plurality of fluororesin layers 12. The total number of the plurality of polyimide layers 11 and the plurality of fluororesin layers 12 is 5 or more.

The plurality of polyimide layers 11 and the plurality of fluororesin layers 12 are alternately stacked along the thickness direction of the insulating layer 10. The fluororesin layer 12 constitutes a first outermost layer (a layer closest to the first main surface 10a) of the insulating layer 10 and a second outermost layer (a layer closest to the second main surface 10b) of the insulating layer 10. The fluororesin layer 12 constituting the first outermost layer is defined as a fluororesin layer 12a. The fluororesin layer 12 constituting the second outermost layer is defined as a fluororesin layer 12b.

The thickness of the polyimide layer 11 is defined as thickness T2. A value obtained by dividing the total thickness T2 of the plurality of polyimide layers 11 by the thickness T1 is 0.95 or less. The value obtained by dividing the total thickness T2 of the plurality of polyimide layers 11 by the thickness T1 is preferably 0.25 or less.

A value obtained by dividing the total thickness T2 of the plurality of polyimide layers 11 by the thickness T1 may be 0.20 or less. The thickness T2 is, for example, 12 μm or more and 25 μm or less.

The thickness of the fluororesin layer 12 is defined as thickness T3. The thickness T3 of the fluororesin layer 12a or the fluororesin layer 12b is 1.0 μm or more and 50 μm or less. The thickness T3 of the fluororesin layer 12a or the fluororesin layer 12b is preferably 3.0 μm or more and 25 μm or less. The thickness T3 of a fluororesin layer 12 other than the fluororesin layer 12a and the fluororesin layer 12b may be different from the thickness T3 of the fluororesin layer 12a or the fluororesin layer 12b. The thickness T3 of a fluororesin layer 12 other than the fluororesin layer 12a and the fluororesin layer 12b is, for example, larger than the thickness T3 of the fluororesin layer 12a or the fluororesin layer 12b. The thickness T3 of a fluororesin layer 12 other than the fluororesin layer 12a and the fluororesin layer 12b is preferably 100 um or more and 140 um or less.

The polyimide layer 11 is preferably made of polyimide having a relative dielectric constant of 2 or more and 4 or less. The relative dielectric constant of the polyimide layer 11 is measured by a cavity resonator method defined in JIS C 2565. The polyimide layer 11 is made of, for example, Kapton (registered trademark) EN-C.

The fluororesin layer 12 is made of, for example, at least one material selected from the group consisting of tetrafluoroethylene-hexafluoropropylene copolymer, tetrafluoroethylene-perfluoroalkyl vinyl ether copolymer, and polytetrafluoroethylene.

The first copper foil 20 and the second copper foil 30 are disposed on the first main surface 10a and the second main surface 10b, respectively. The first copper foil 20 and the second copper foil 30 are made of, for example, electrolytic copper foil. The first copper foil 20 and the second copper foil 30 may be made of rolled copper foil.

The printed wiring board substrate 100 is manufactured, for example, by stacking a plurality of polyimide sheets, a plurality of fluororesin sheets and two copper foils and then vacuum hot pressing the same. However, the method of manufacturing the printed wiring board substrate 100 is not limited thereto.

### <Effects of Printed Wiring Board Substrate 100>

Hereinafter, the effects of the printed wiring board substrate 100 will be described.

In a printed wiring board substrate having an insulating layer which is obtained by stacking a plurality of polyimide layers and a plurality of fluororesin layers, the larger the value obtained by dividing the total thickness of the plurality of polyimide layers by the thickness of the insulating layer is, the better the bending property will be. However, as the value obtained by dividing the total thickness of the plurality of polyimide layers by the thickness of the insulating layer increases, the high-frequency property tends to deteriorate.

In the printed wiring board substrate 100, since the value obtained by dividing the total thickness of the plurality of polyimide layers 11 by the thickness T1 is 0.95 or less, the bending property is improved.

In addition, in the printed wiring board substrate 100, since the first outermost layer in contact with the first copper foil 20 and the second outermost layer in contact with the second copper foil 30 are the fluororesin layer 12a and the fluororesin layer 12b, respectively, which are excellent in high-frequency property, and the thickness T3 of the fluororesin layer 12a or the fluororesin layer 12b is 1.0 μm or more and 50 μm or less, even when the value obtained by dividing the total thickness of the plurality of polyimide layers 11 by the thickness T1 is 0.95 or less, the printed wiring board substrate exhibits excellent high-frequency property. Thus, according to the printed wiring board substrate 100, it is possible to achieve both good high-frequency property and good bending property.

A printed wiring board is formed from the printed wiring board substrate 100 by patterning the first copper foil 20 and the second copper foil 30 into wirings. When the total number of the plurality of polyimide layers 11 and the plurality of fluororesin layers 12 is less than 5, warpage may occur when patterning the first copper foil 20 and the second copper foil 30. In the printed wiring board substrate 100, since the total number of the plurality of polyimide layers 11 and the plurality of fluororesin layers 12 is 5 or more, it is possible to prevent the occurrence of warpage when patterning the first copper foil 20 and the second copper foil 30.

In the case where the first copper foil 20 and the second copper foil 30 are made of rolled copper foil, since the rolled copper foil has good elongation, it is possible to achieve good bending property. When the polyimide layer 11 is made of polyimide having a relative dielectric constant of 2 or more and 4 or less, it is possible to further improve the high-frequency property. When the thermal expansion coefficient of the insulating layer 10 is 16 ppm/K or more and 100 ppm/K or less, it is possible to prevent the occurrence of warpage in the substrate.

When the thickness T1 is 170 μm or less, it is possible to achieve good bending property. More specifically, in this case, the bending radius of the insulating layer 10can be 0.5 mm or less.

### (Printed Wiring Board According to an Embodiment)

A printed wiring board according to an embodiment will be described. Hereinafter, the printed wiring board according to the embodiment is defined as a printed wiring board 200.

### <Configuration of Printed Wiring Board 200>

Hereinafter, the configuration of the printed wiring board 200 will be described.

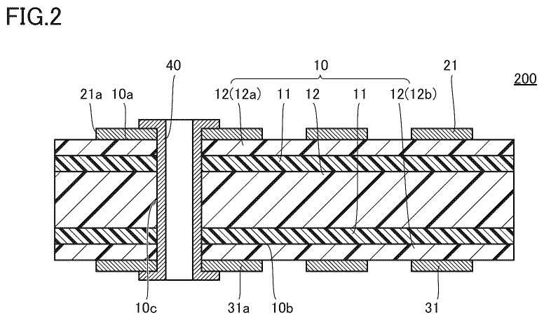

FIG. 2 is a cross-sectional view of the printed wiring board 200. As illustrated in FIG. 2, the printed wiring board 200 includes an insulating layer 10, a first wiring 21, and a second wiring 31. The first wiring 21 is disposed on the first main surface 10a. The second wiring 31 is disposed on the second main surface 10b.

The printed wiring board 200 is formed from the printed wiring board substrate 100. More specifically, the printed wiring board 200 is formed by patterning the first copper foil 20 to form the first wiring 21, and patterning the second copper foil 30 to form the second wiring 31.

Patterning the first copper foil 20 (or the second copper foil 30) is performed, for example, by attaching a dry film resist to the first copper foil 20 (or the second copper foil 30), exposing and developing the attached dry film resist to form a mask, and etching the first copper foil 20 (or the second copper foil 30) exposed from the mask.

In the printed wiring board 200, the transmission loss per 100 mm of the first wiring 21 at 50 GHz and the transmission loss per 100 mm of the second wiring 31 at 50 GHz are preferably 7 dB or less. The transmission loss of the first wiring 21 and the transmission loss of the second wiring 31 are measured by using a network analyzer.

In the printed wiring board 200, the insulating layer 10 may be formed with a through hole 10c. The through hole 10c penetrates the insulating layer 10 in the thickness direction. The through hole 10c is formed to overlap with a land portion 21a of the first wiring 21 and a land portion 31a of the second wiring 31 in a plan view.

A conductor layer 40 is disposed on the inner wall surface of the through hole 10c, on the side surface and the upper surface of the land portion 21a around the through hole 10c, and on the side surface and the upper surface of the land portion 31a around the through hole 10c. Thus, the first wiring 21 and the second wiring 31 are electrically connected to each other. The conductor layer 40 may be filled in the through hole 10c. The conductor layer 40 is made of, for example, copper.

### (Multilayer Printed Wiring Board According to an Embodiment)

A multilayer printed wiring board according to an embodiment will be described. Hereinafter, the multilayer printed wiring board according to the embodiment is defined as a multilayer printed wiring board 300.

### <Configuration of Multilayer Printed Wiring Board 300>

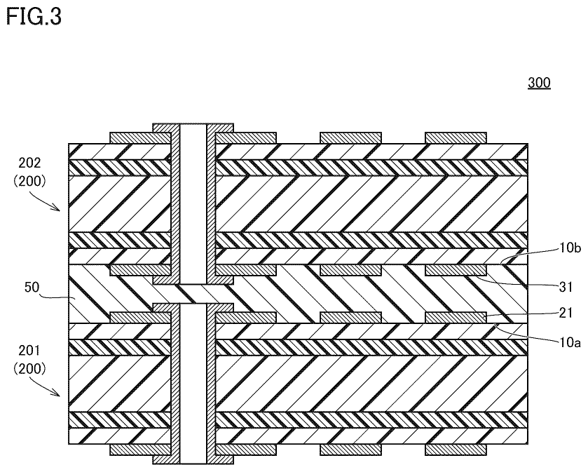

FIG. 3 is a cross-sectional view of the multilayer printed wiring board 300. As illustrated in FIG. 3, the multilayer printed wiring board 300 includes a plurality of printed wiring boards 200. Although two printed wiring boards are illustrated in FIG. 3, the number of the plurality of printed wiring boards 200 is not limited thereto.

The multilayer printed wiring board 300 further includes an adhesive layer 50. One of the two adjacent printed wiring boards 200 is defined as a printed wiring board 201, and the other one of the two adjacent printed wiring boards 200 is defined as a printed wiring board 202. The adhesive layer 50 is disposed between the first main surface 10a of the printed wiring board 201 and the second main surface 10b of the printed wiring board 202 so as to cover the first wiring 21 of the printed wiring board 201 and the second wiring 31 of the printed wiring board 202. The adhesive layer 50 is made of, for example, an epoxy adhesive.

### (Example of Printed Circuit Board)

In order to evaluate the relationship between the thickness T1 and the thickness T2 of the printed wiring board and the thickness T3 of the outermost fluororesin layer 12 (the fluororesin layer 12a, the fluororesin layer 12b) and the fluororesin layer 12 other than the outermost layer, and the transmission loss of the wirings (the first wiring 21 and the second wiring 31), samples A1 to A9 were prepared. In samples A1 to A9, the total number of the plurality of polyimide layers 11 and the plurality of fluororesin layers 12 was 5.

A condition that the thickness T3 of the fluororesin layer 12a or the fluororesin layer 12b is 1 μm or more and 50 μm or less is defined as condition A. A condition that the value obtained by dividing the total thickness T2 of the plurality of polyimide layers 11 by the thickness T1 is 0.95 or less is defined as condition B. As listed in Table 1, samples A1 to A9 satisfy conditions A and B. In other words, samples A1 to A9 correspond to the printed wiring board 200.

TABLE 1

| | | | Thickness T3 (μm) | | Total | Transmission |
|---|---|---|---|---|---|---|
| | Thickness | Thickness | | The | Thickness | loss per 100 mm |
| | T1 | T2 | Outermost | other | T2/Thickness | wiring at 50 GHz |
| Sample | (μm) | (μm) | layer | layer | T1 | (dB) |
| A1 | 130 | 12 | 3 | 100 | 0.18 | −2.7 |
| A2 | 150 | 12 | 3 | 120 | 0.16 | −2.5 |
| A3 | 170 | 12 | 3 | 140 | 0.14 | −2.3 |
| A4 | 148 | 12 | 12 | 100 | 0.16 | −2.4 |
| A5 | 168 | 12 | 12 | 120 | 0.14 | −2.2 |
| A6 | 188 | 12 | 12 | 140 | 0.13 | −2.0 |
| A7 | 174 | 12 | 25 | 100 | 0.14 | −2.1 |
| A8 | 194 | 12 | 25 | 120 | 0.12 | −2.0 |
| A9 | 214 | 12 | 25 | 140 | 0.11 | −1.8 |
| A10 | 170 | 85 | 0 | 0 | 1.00 | −6.3 |

In addition, sample A10 and sample A11 were prepared as comparative examples. In sample A10, the insulating layer was formed only by two polyimide layers 11 (in other words, the thickness T3 of the fluororesin layer 12 of the outermost layer and the thickness T3 of the fluororesin layer 12 other than the outermost layer were both 0). Sample A11 was not listed in Table 1, and the insulating layer thereof was formed only by a liquid crystal polymer layer. In sample A11, the thickness of the insulating layer was 100 μm.

The transmission loss of each sample of A1 to A11 was measured by using a microstrip line in which the impedance formed by a wiring on the printed wiring board was adjusted to 50 Ω. In samples A1 to A9, the transmission loss per 100 mm wiring at 50 GHz was smaller than that of sample A11. More specifically, in samples A1 to A9, the transmission loss per 100 mm wiring at 50 GHz was 7 dB or less. In sample A10, the transmission loss per 100 mm wiring at 50 GHz was larger than that of sample A11. Thus, it was obvious that the printed wiring board 200 has good high-frequency property.

Sample A10 can be bent with a bending radius of 0.5 mm or more. As the thickness T1 decreases, the high-frequency property decreases (the transmission loss of the wiring increases). On the other hand, as the thickness T1 decreases, the bending property increases.

Even for those of samples A1 to A9 with a thickness T1 of 170 μm or less (samples A1 to A5), in other words, those of samples A1 to A9 bendable with a bending radius of 0.5 mm or more, the transmission loss per 100 mm wiring at 50 GHz was smaller than that of sample A11. Thus, it was obvious that the printed wiring board 200 has both good high-frequency property and good bending property.

In order to evaluate the bending property of samples A4 and A8, a mandrel test defined in JIS K5600-5 was performed. The mandrel test was performed 10 times with a mandrel having a diameter of 2 mm. The mandrel test was performed with the microstrip line arranged at the fold portion. After 10 times of the mandrel test with a mandrel having a diameter of 2 mm, the probe was brought into contact with a pad of the microstrip line disposed at the end of the printed wiring board to determine the presence or absence of wire disconnection in the microstrip line.

TABLE 2

| | | | Thickness T3 (μm) | | Total | Wire |
|---|---|---|---|---|---|---|
| | Thickness | Thickness | | The | Thickness | disconnection |
| | T1 | T2 | Outermost | other | T2/Thickness | after mandrel |
| Sample | (μm) | (μm) | layer | layer | T1 | test of 10 times |
| A4 | 148 | 12 | 12 | 100 | 0.16 | None |
| A8 | 194 | 12 | 25 | 120 | 0.12 | None |

As listed in Table 4, in samples A4 and A8, no wire disconnection was found in the microstrip line after 10 times of the mandrel test with a mandrel having a diameter of 2 mm. Thus, it was obvious that the printed wiring board 200 has good bending property.

### (Example of Multilayer Printed Wiring Board)

In order to evaluate the relationship between the thickness T1 and the thickness

T2 of each of the printed wiring boards and the thickness T3 of the outermost fluororesin layer 12 (the fluororesin layer 12a, the fluororesin layer 12b) and the fluororesin layer 12 other than the outermost layer included in the multilayer printed wiring board, and the transmission loss of the wirings (the first wiring 21 and the second wiring 31), samples B1 to B25 were prepared. Samples B1 to B25 were prepared by stacking two printed wiring boards. In samples B1 to B25, the total number of the plurality of polyimide layers 11 and the plurality of fluororesin layers 12 was 5.

A condition that the thickness T3 of the fluororesin layer 12a or the fluororesin layer 12b is 1 μm or more and 50 μm or less is defined as condition A. A condition that the value obtained by dividing the total thickness T2 of the plurality of polyimide layers 11 by the thickness T1 is 0.95 or less is defined as condition B. As listed in Table 3, samples B1 to B25 satisfy conditions A and B. In other words, samples B1to B25 correspond to the multilayer printed wiring board 300.

TABLE 3

| | | | Thickness T3 (μm) | | Total | Transmission |
|---|---|---|---|---|---|---|
| | Thickness | Thickness | | The | Thickness | loss per 100 mm |
| | T1 | T2 | Outermost | other | T2/Thickness | wiring at 50 GHz |
| Sample | (μm) | (μm) | layer | layers | T1 | (dB) |
| B1 | 130 | 12 | 3 | 100 | 0.18 | −3.7 |
| B2 | 156 | 25 | 3 | 100 | 0.32 | −4.0 |
| B3 | 150 | 12 | 3 | 120 | 0.16 | −3.4 |
| B4 | 176 | 25 | 3 | 120 | 0.28 | −3.6 |
| B5 | 170 | 12 | 3 | 140 | 0.14 | −3.1 |
| B6 | 196 | 25 | 3 | 140 | 0.26 | −3.4 |
| B7 | 148 | 12 | 12 | 100 | 0.16 | −3.2 |
| B8 | 174 | 25 | 12 | 100 | 0.29 | −3.4 |
| B9 | 168 | 12 | 12 | 120 | 0.14 | −2.9 |
| B10 | 194 | 25 | 12 | 120 | 0.26 | −3.2 |
| B11 | 188 | 12 | 12 | 140 | 0.13 | −2.7 |
| B12 | 214 | 25 | 12 | 140 | 0.23 | −3.0 |
| B13 | 174 | 12 | 25 | 100 | 0.14 | −2.8 |
| B14 | 200 | 25 | 25 | 100 | 0.25 | −3.0 |
| B15 | 194 | 12 | 25 | 120 | 0.12 | −2.6 |
| B16 | 220 | 25 | 25 | 120 | 0.23 | −2.8 |
| B17 | 214 | 12 | 25 | 140 | 0.11 | −2.5 |
| B18 | 168 | 42 | 28 | 28 | 0.50 | −4.2 |
| B19 | 101 | 25 | 17 | 17 | 0.50 | −5.2 |
| B20 | 169 | 62 | 15 | 15 | 0.73 | −5.4 |
| B21 | 86 | 25 | 12 | 12 | 0.58 | −6.0 |
| B22 | 60 | 12 | 12 | 12 | 0.40 | −6.3 |
| B23 | 60 | 15 | 10 | 10 | 0.50 | −6.7 |
| B24 | 169 | 77 | 5 | 5 | 0.91 | −6.6 |
| B25 | 169 | 80 | 3 | 3 | 0.95 | −6.9 |
| B26 | 170 | 85 | 0 | 0 | 1.00 | −7.4 |

In addition, sample B26 and sample B27 were prepared as comparative examples. In sample B26, the insulating layer was formed only by two polyimide layers 11 (in other words, the thickness T3 of the fluororesin layer 12 of the outermost layer and the thickness T3 of the fluororesin layer 12 other than the outermost layer were both 0). Sample B27 was not listed in Table 3, and the insulating layer thereof was formed only by a liquid crystal polymer layer. In sample B27, the thickness of the insulating layer was 100 μm.

The transmission loss of each sample of B1 to B27 was measured by using a strip line in which the impedance formed by a wiring on the multilayer printed wiring board was adjusted to 50 Ω. In samples B1 to B25, the transmission loss per 100 mm wiring at 50 GHz was smaller than that of sample B27. More specifically, in samples B1 to B25, the transmission loss per 100 mm wiring at 50 GHz was 7 dB or less. In sample B26, the transmission loss per 100 mm wiring at 50 GHz was larger than that in sample B27. Thus, it was obvious that the multilayer printed wiring board 300 has good high-frequency property.

Sample B26 can be bent with a bending radius of 0.5 mm or more. As the thickness T1 decreases, the high-frequency property decreases (the transmission loss of the wiring increases). On the other hand, as the thickness T1 decreases, the bending property increases.

Even for those of samples B1 to B25 with a thickness T1 of 170 μm or less (samples B1 to B3, sample B5, sample B7, sample B9, and samples B18 to B25), in other words, those of samples B1 to B25 bendable with a bending radius of 0.5 mm or more, the transmission loss per 100 mm wiring at 50 GHz was smaller than that of sample B27. Thus, it was obvious that the multilayer printed wiring board 300 has both good high-frequency property and good bending property.

In order to evaluate the bending property of sample B7 and sample B15, a mandrel test defined in JIS K5600-5 was performed. The mandrel test was performed 10 times with a mandrel having a diameter of 2 mm. The mandrel test was performed with the strip line arranged at the fold portion. After 10 times of the mandrel test with a mandrel having a diameter of 2 mm, the probe was brought into contact with a pad of the microstrip line disposed at the end of the multilayer printed wiring board to determine the presence or absence of wire disconnection in the microstrip line.

TABLE 4

| | | | Thickness T3 (μm) | | Total | Wire |
|---|---|---|---|---|---|---|
| | Thickness | Thickness | | The | Thickness | disconnection |
| | T1 | T2 | Outermost | other | T2/Thickness | after mandrel test |
| Sample | (μm) | (μm) | layer | layers | T1 | of 10 times |
| B7 | 148 | 12 | 12 | 100 | 0.16 | None |
| B15 | 194 | 12 | 25 | 120 | 0.12 | None |

As listed in Table 4, in samples B7 and B15, no wire disconnection was found in the strip line after 10 times of the mandrel test with a mandrel having a diameter of 2 mm. Thus, it was obvious that the multilayer printed wiring board 300 has good bending property.

It should be understood that the embodiments disclosed herein have been presented for the purpose of illustration and description but not limited in all aspects.

It is intended that the scope of the present invention is not limited to the description above but defined by the scope of the claims and encompasses all modifications equivalent in meaning and scope to the claims.

### REFERENCE SIGNS LIST

10: insulating layer; 10a: first main surface; 10b: second main surface; 10c: through hole; 11: polyimide layer; 12: fluororesin layer; 12a, 12b: fluororesin layer; 20: first copper foil; 21: first wiring; 21a: land portion; 30: second copper foil; 31: second wiring; 31a: land portion; 40: conductor layer; 50: adhesive layer; 100: printed wiring board substrate; 200, 201, 202: printed wiring board; 300: multilayer printed wiring board; T1, T2, T3: thickness.

1. A printed wiring board substrate comprising:
an insulating layer;
a first copper foil; and
a second copper foil,
wherein the insulating layer has a first main surface and a second main surface opposite to the first main surface,
the insulating layer includes a plurality of polyimide layers and a plurality of fluororesin layers,
the total number of the plurality of polyimide layers and the plurality of fluororesin layers is 5 or more,
each of the plurality of polyimide layers and each of the plurality of fluororesin layers are alternately stacked along a thickness direction of the insulating layer,
one of the plurality of fluororesin layers constitutes a first outermost layer which is an outermost layer on the side of the first main surface,
another one of the plurality of fluororesin layers constitutes a second outermost layer which is an outermost layer on the side of the second main surface,
the first outermost layer and the second outermost layer each have a thickness of 1.0 μm or more and 50 μm or less,
a value obtained by dividing a total thickness of the plurality of polyimide layers by a thickness of the insulating layer is 0.95 or less, and
the first copper foil and the second copper foil are disposed on the first main surface and the second main surface, respectively.

2. The printed wiring board substrate according to claim 1, wherein
the plurality of fluororesin layers are made of at least one material selected from the group consisting of tetrafluoroethylene-hexafluoropropylene copolymer, tetrafluoroethylene-perfluoroalkyl vinyl ether copolymer, and polytetrafluoroethylene.

3. The printed wiring board substrate according to claim 1, wherein
the plurality of polyimide layers are made of polyimide having a relative dielectric constant of 2 or more and 4 or less.

4. The printed wiring board substrate according to claims 1, wherein
the first copper foil and the second copper foil are made of electrolytic copper foil.

5. The printed wiring board substrate according to claims 1, wherein
the first copper foil and the second copper foil are made of rolled copper foil.

6. The printed wiring board substrate according to claims 1, wherein
the insulating layer has a thermal expansion coefficient of 16.0 ppm/K or more and 100 ppm/K or less.

7. The printed wiring board substrate according to claims 1, wherein
the insulating layer has a thickness of 170 μm or less.

8. A printed wiring board comprising:
an insulating layer;
a first wiring; and
a second wiring,
wherein the insulating layer has a first main surface and a second main surface opposite to the first main surface,
the insulating layer includes a plurality of polyimide layers and a plurality of fluororesin layers,
the total number of the plurality of polyimide layers and the plurality of fluororesin layers is 5 or more,
each of the plurality of polyimide layers and each of the plurality of fluororesin layers are alternately stacked along a thickness direction of the insulating layer,
one of the plurality of fluororesin layers constitutes a first outermost layer which is an outermost layer on the side of the first main surface,
another one of the plurality of fluororesin layers constitutes a second outermost layer which is an outermost layer on the side of the second main surface,
the first outermost layer and the second outermost layer each have a thickness of 1.0 μm or more and 50 μm or less,
a value obtained by dividing a total thickness of the plurality of polyimide layers by a thickness of the insulating layer is 0.95 or less, and
the first wiring and the second wiring are disposed on the first main surface and the second main surface, respectively.

9. The printed wiring board according to claim 8, wherein
a transmission loss per 100 mm of the first wiring at 50 GHz and a transmission loss per 100 mm of the second wiring at 50 GHz are 7 dB or less.

10. A multilayer printed wiring board comprising:
a plurality of printed wiring boards,
each of the plurality of printed wiring boards being the printed wiring board according to claim 8
